(19) United States
(12) Patent Application Publication
(10) Pub. No.: US 2005/0255814 A1
(43) Pub. Date: Nov. 17, 2005

(54) Apparatus and method for compensating for an offset of a power amplifier in a mobile communication system

(75) Inventors: Yoo-Seung Song, Suwon-si (KR); Jae-Hyok Lee, Seoul (KR); Seung-Hwan Lee, Seoul (KR); Ki-Hwan Hwang, Suwon-si (KR); Jae-Ho Jeon, Seongnam-si (KR); Seung-Joo Maeng, Seongnam-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/126,251

(22) Filed: May 11, 2005

(30) Foreign Application Priority Data
May 11, 2004 (KR) 2004-33235

(51) Int. Cl. H04B 1/04; H03C 1/62; H04B 17/00

(52) U.S. Cl. 455/114.3; 455/115.1; 455/126; 375/297

(57) ABSTRACT

An apparatus and method for compensating for an error of a power amplifier in a digital mobile communication system having a predistorter are provided. The apparatus and method comprise a gain compensator for pre-correcting a gain error occurring in a path of each phase signal while an in-phase signal and a quadrature-phase signal, output from the predistorter, undergo digital-to-analog (D/A) conversion; a digital-to-analog converter (DAC) for converting a digital signal output from the gain compensator into an analog signal; and a transmission signal converter for converting an output of the DAC into a radio frequency (RF) signal, and outputting the RF signal to the power amplifier.

### PRIORITY

This application claims priority under 35 U.S.C. § 119(a) to an application entitled “Apparatus and Method for Compensating for Offset of Power Amplifier in a Mobile Communication System” filed in the Korean Intellectual Property Office on May. 11, 2004 and assigned Serial No. 2004-33235, the entire contents of which are incorporated herein by reference.

### BACKGROUND OF THE INVENTION

1. Field of the Invention:

The present invention relates generally to an apparatus and method for compensating for an offset of a base station in a mobile communication system. In particular, the present invention relates to an apparatus and method for compensating for an offset of a power amplifier in a base station.

2. Description of the Related Art:

In general, mobile communication systems have been developed to communicate with mobile stations using radio signals. The mobile communication systems have evolved from analog systems into digital systems. The mobile communication systems are classified into synchronous systems and asynchronous systems, all of which have been developing into advanced systems capable of supporting high-speed data transmission.

The mobile communication system performs communication with a mobile station using radio frequency (RF) signals regardless of a position of the mobile station. Therefore, a base station of the mobile communication system has a power amplifier for transmitting data to the mobile station. The power amplifier should transmit transmission signals with appropriate power according to a distance and an environment between the mobile station and the base station.

The power amplifier will now be described with reference to FIG. 1. FIG. 1 is a conceptual graph illustrating an input-output characteristic of a power amplifier.

A power amplifier is a device for amplifying an input signal. Therefore, the power amplifier is designed such that it amplifies an input signal to a desired signal level. However, as illustrated in FIG. 1, an actual power amplifier cannot achieve linear power amplification over the full band. That is, for a desired signal 100 of FIG. 1, an output 110 of the actual power amplifier draws a different curve. This is because when a signal with a level higher than a specific level is received, the power amplifier amplifies the received signal at a gain lower than a desired gain. In order to compensate for a difference between the desired gain and the actual gain in the power amplifier, the mobile communication system inputs a predistorted signal 120 obtained by applying predistortion to an input signal to the power amplifier so that the power amplifier can output the desired signal 100. In order to input the predistorted signal to the power amplifier in this manner, a predistorter is required.

A typical example of a power amplifier actually used in the mobile communication system will now be described with reference to FIG. 2. FIG. 2 is a diagram illustrating peripheral circuits of a power amplifier, for which a predistorter is used, in a digital mobile communication system.

The digital mobile communication system uses digital signals as transmission signals. Therefore, a digital predistorter (DPD) 201 of FIG. 2 predistorts a complex digital input signal, and outputs the predistorted digital signal to a digital-to-analog converter (DAC) 203. The DAC 203 converts the predistorted digital signal into an analog signal for amplification in a power amplifier (PA) 211, and outputs the analog signal to a low-pass filter (LPF) 205. The low-pass filter 205 removes undesired waves from the analog signal output from the DAC 203, and outputs the undesired wave-removed signal to a mixer 207. The mixer 207 up-converts the undesired wave-removed signal into an RF-band signal, and outputs the up-converted signal to a band-pass filter (BPF) 209. The band-pass filer 209 filters off signals in an undesired band to remove the undesired waves occurring during the up-conversion, and outputs the filtered signal to the power amplifier 211. The power amplifier 211 power-amplifies the input signal to a predetermined signal level.

In this case, the power amplifier circuit should determine whether the predistorted signal underwent correct predistortion. In other words, the power amplifier circuit determines whether a signal actually amplified by the power amplifier 211 is substantially coincident with a signal in the desired level. If the signal amplification to the desired level failed, the following problems may occur. If a transmission signal is amplified to a level higher than the desired level, the output signal serves as a strong interference to the signals transmitted to other mobile stations in the vicinity of the mobile communication system, affecting the entire system performance. In contrast, if the transmission signal is amplified to a level lower than the desired level, a mobile station receiving the transmission signal suffers degradation in quality-of-service (QoS) or an increase in transmission error rate, thus requiring many retransmissions. This causes a reduction in the entire throughput of the system.

Therefore, a part of the signals output from the power amplifier 211 is fed back, and the feedback signal is used for determining whether the desired amplification is being performed in the power amplifier 211. A part of the signals amplified by the power amplifier 211 is input to a band-pass filter (BPF) 221. The band-pass filter 221 passes only the signal in a desired band among input signals, and outputs the filtered signal to a mixer 223. The mixer 223 down-converts the filtered signal, and outputs the down-converted signal to a low-pass filter (LPF) 225 to remove undesired waves generated during the down conversion. The low-pass filter 225 low-pass-filters the down-converted signal, and outputs the low-pass-filtered signal to an analog-to-digital converter (ADC) 227. The ADC 227 converts the input analog signal back into a digital signal, and outputs the digital signal to a digital quadrature digital modulator (DQDM) 229. A signal passing through the ADC 227 generates various images at a multiple of a sampling rate. The DQDM 229 shifts the center of a desired signal band to a direct current (DC) band to remove the images, and then removes the remaining images using a low-pass filter.

A device for determining a value for predistortion is added at the end of the DQDM 229. Although not illustrated in FIG. 1, this device will be described below. A method for determining the value for predistortion can be divided into a method using a memory in which the predistortion value is previously stored, and a method of calculating the predistortion value in real time. After calculating the predistortion value in one of the methods, the device detects a level of a transmission signal and inputs a predistortion value to the digital predistorter 201 according to the level of the transmission signal. Then the digital predistorter 201 predistorts the input signal according to the predistortion value.

In the foregoing predistortion scheme, gain mismatch occurs in the DAC 203. In addition, performance of the digital predistorter 201 is deteriorated due to a DC offset of the ADC 227. The DAC gain mismatch and the DC offset will be described in detail below.

First, the DAC gain mismatch of the DAC 203 will be described. Generally, gain mismatch in the DAC 203 is related to a sampling rate. The “sampling rate” in the DAC 203 refers to how many samples are used to convert a digital signal into an analog signal. A higher sampling rate is required in a system requiring a higher data rate. In other words, as a rate of input data increases, a higher sampling rate is required.

However, commercial products are generally used for the DAC used in the mobile communication system. In the commercial DAC, if an input data rate is greater than or equal to 70 Msps (mega samples per second), digital noise coupling occurs, causing deterioration in output image rejection performance of the DAC 203 due to autocorrelation. From the analysis on an output signal spectrum of the DAC 203, it is noted that an image occurs in an adjacent band of a transmission signal band. As a result, the generation of an image in the adjacent band of the transmission signal band occurs when in-phase (I) and quadrature-phase (Q) path signals which are inputs of the DAC 203 are different from each other in terms of a gain.

Herein, the gain mismatch between the I signal path and the Q signal path is referred to as “the DAC gain mismatch” of the DAC 203. In the general communication system, the DAC gain mismatch of the DAC 203 serves to increase an output spectrum spurious of a final transmission signal, so that the final transmission signal may not satisfy the transmitter spurious emission limit. In other words, the digital predistorter 201, when implemented, may fail to remove the spurious component due to the DAC gain mismatch of the DAC 203. As a result, the spurious component included in the signal band serves as a noise in the transmission signal, deteriorating QoS of the communication system.

Next, the DC offset of the ADC 227 will be described. The ADC 227 is used for a circuit for monitoring whether the power amplifier 211 is achieving the desired amplification. Similarly, the commercial chips are generally used for the ADC 227. The commercial chip for the ADC 227 generates DC signal components regardless of the center frequency of an input signal in the A/D conversion process. The DC signal components cause considerable performance degradation and places limitations on a receiver system or a feedback system.

More specifically, in a zero-intermediate frequency (ZIF) receiver system, a DC-offset component is added to a signal band. The DC-offset component serves as a noise to a desired signal, decreasing a signal-to-noise ratio (SNR). The decrease in SNR increases a bit error rate (BER), resulting in performance deterioration. In a digital intermediate frequency (IF) receiver system, a corresponding offset component is located in the center frequency, restricting a characteristic of a low-pass filter. This is equally applied to the feedback system. Therefore, in the power amplifier circuit, if the feedback system using the digital predistorter 201 does not compensate for the DC offset, an output signal of the ADC 227 suffers considerable fluctuations. In other words, the digital predistorter 201 fails to achieve normal predistortion.

As described above, accurate predistortion cannot be achieved due to the errors occurring in the DAC and the ADC used for the power amplifier circuit with the predistorter in the digital system, causing inaccurate power amplification.

### SUMMARY OF THE INVENTION

It is, therefore, an object of the present invention to provide an apparatus and method for correcting an error occurring in a power amplifier circuit with a predistorter in a digital system.

It is another object of the present invention to provide an apparatus and method for correcting an error occurring in a digital-to-analog converter (DAC) in a power amplifier circuit with a predistorter in a digital system.

It is further another object of the present invention to provide an apparatus and method for correcting an error occurring in an analog-to-digital converter (ADC) in a power amplifier circuit with a predistorter in a digital system.

According to one aspect of the present invention, there is provided an apparatus and method for compensating for an error of a power amplifier in a digital mobile communication system having a predistorter. The apparatus comprises a gain compensator for pre-correcting a gain error occurring in a path of each phase signal while an in-phase signal and a quadrature-phase signal, output from the predistorter, undergo digital-to-analog (D/A) conversion; a digital-to-analog converter (DAC) for converting a digital signal output from the gain compensator into an analog signal; and a transmission signal converter for converting an output of the DAC into a radio frequency (RF) signal, and outputting the RF signal to the power amplifier.

### BRIEF DESCRIPTION OF THE DRAWINGS

The above and other objects, features and advantages of the present invention will become more apparent from the following detailed description when taken in conjunction with the accompanying drawings in which:

FIG. 1 is a conceptual graph illustrating an input-output characteristic of a conventional power amplifier;

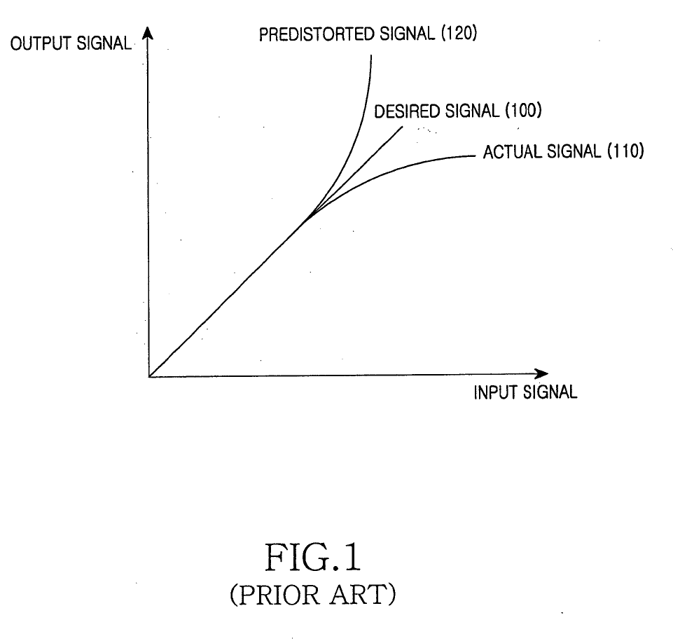

FIG. 2 is a diagram illustrating peripheral circuits of a conventional power amplifier, for which a predistorter is used, in a digital mobile communication system;

FIG. 3 is a diagram illustrating peripheral circuits of a power amplifier, for which a predistorter is used, in a digital mobile communication system according to an embodiment of the present invention;

FIG. 4 is a detailed block diagram of an offset measurement and compensation block according to an embodiment of the present invention;

FIG. 5 is a detailed block diagram of a gain measurer according to an embodiment of the present invention;

FIG. 6 is a detailed block diagram of a gain compensator according to an embodiment of the present invention;

FIG. 7 is a graph illustrating simulation results for an output of a DAC in a code division multiple access 2000 (CDMA2000) 1× system according to an embodiment of the present invention and according to the prior art;

FIG. 8 is a graph illustrating simulation results for an output of a power amplifier in a CDMA2000 1× system according to an embodiment of the present invention and according to the prior art

FIG. 9A is a graph illustrating simulation results for a frequency-power characteristic in the case where an output of an ADC is ideal in a CDMA2000 1× system;

FIG. 9B is a simulation graph for a frequency-power characteristic;

FIG. 9C is a graph illustrating an envelope;

FIGS. 9D and 9E are graphs illustrating simulation results for the case where there is no DC offset in an output of an ADC in a CDMA2000 1× system.

Throughout the drawings, the same or similar elements are denoted by the same reference numerals.

### DETAILED DESCRIPTION OF AN EXEMPLARY EMBODIMENT

A preferred embodiment of the present invention will now be described in detail with reference to the accompanying drawings. In the following description, a detailed description of known functions and configurations incorporated herein has been omitted for conciseness.

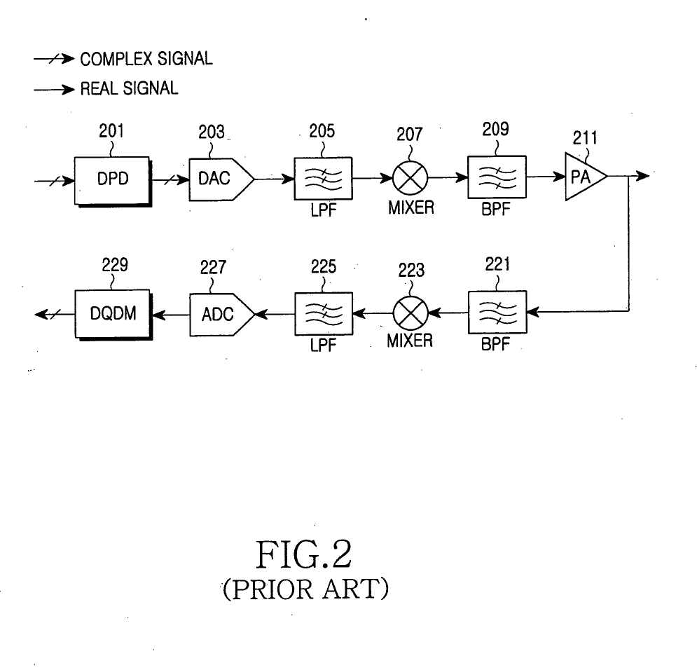

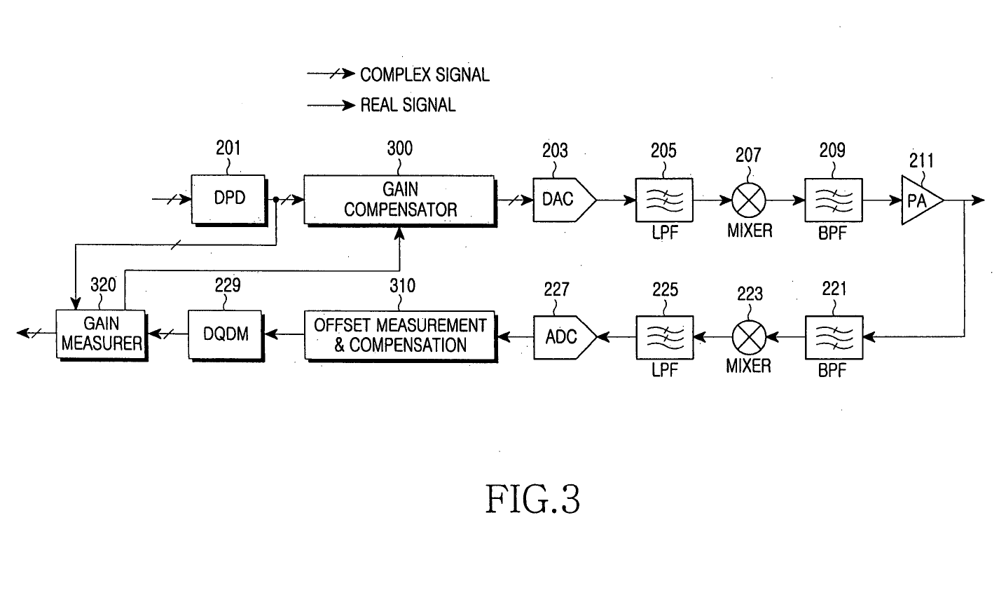

FIG. 3 is a diagram illustrating peripheral circuits of a power amplifier, for which a predistorter is used, in a digital mobile communication system. With reference to FIG. 3, a description will now be made of peripheral circuits of a predistorter in the digital mobile communication system according to an embodiment of the present invention. In FIG. 3, the same elements as those in FIG. 2 are denoted by the same reference numerals.

As described in the prior art section, a digital predistorter (DPD) 201 predistorts a complex digital input signal. A predistortion value depends upon a level of the input signal, and the digital predistorter 201 receives the predistortion value through a feedback signal. The digital predistorter 201 predistorts the input signal using the predistortion value, and outputs the predistorted signal to a gain compensator 300. The gain compensator 300 compensates for a DAC gain mismatch. A description of an operation of the gain compensator 300 will be given after a description of the entire configuration. The signal gain-compensated by the gain compensator 300 is output to a digital-to-analog converter (DAC) 203. The DAC 203 converts a digital input signal into an analog signal for amplification in a power amplifier (PA) 211, and outputs the analog signal to a low-pass filter (LPF) 205. The low-pass filter 205 removes undesired waves or signals occurring during the D/A conversion from the analog signal output from the DAC 203, and outputs the undesired wave-removed signal to a mixer 207.

The mixer 207 up-converts the undesired wave-removed signal into a radio frequency (RF)-band signal, and outputs the up-converted signal to a band-pass filter (BPF) 209. The band-pass filer 209 filters off signals in an undesired band to remove the undesired waves occurring during the up-conversion, and outputs the filtered signal to the power amplifier 211. The power amplifier 211 power-amplifies the input signal to a predetermined signal level. The power-amplified signal is a signal that underwent predistortion and compensation for D/A conversion distortion. Herein, the low-pass filter 205, the mixer 207, and the band-pass filter 209 comprise a transmission signal converter.

As described in the prior art section, the power amplifier circuit should have a feedback circuit to monitor whether the predistorted signal underwent correct predistortion. In other words, the power amplifier circuit determines whether a signal amplified by the power amplifier 211 is substantially coincident with a signal in the desired level through the feedback circuit. Therefore, a part of the signals output from the power amplifier 211 is fed back, and the feedback signal is used for monitoring whether the desired amplification is being performed in the power amplifier 211.

A part of the signals amplified by the power amplifier 211 is input to a band-pass filter (BPF) 221. The band-pass filter 221 passes only the signal in a desired band among input signals, and outputs the filtered signal to a mixer 223. The mixer 223 down-converts the filtered signal, and outputs the down-converted signal to a low-pass filter (LPF) 225 to remove undesired waves generated during the down conversion. The low-pass filter 225 low-pass-filters the down-converted signal, and outputs the low-pass-filtered signal to an analog-to-digital converter (ADC) 227. The ADC 227 converts the input analog signal back into a digital signal. Herein, the band-pass filter 221, the mixer 223, the low-pass filter 225, and the ADC 227 comprise a feedback converter.

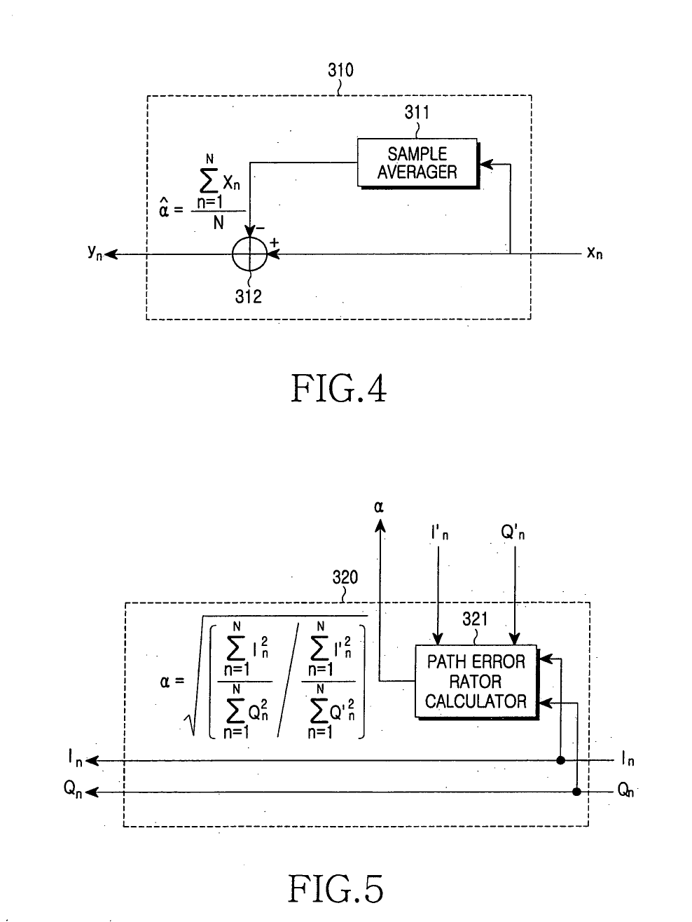

The feedback converter comprises the ADC 227 at the end thereof. An offset measurement and compensation block 310 according to an embodiment of the present invention is connected to an output terminal of the feedback converter. Therefore, the offset measurement and compensation block 310 measures a direct current (DC) offset occurring during the A/D conversion, compensates for the DC offset, and outputs the offset-compensated signal to a digital quadrature digital modulator (DQDM) 229. A detailed description of the offset measurement and compensation block 310 will be made later with reference to FIG. 4 after a description of all the elements.

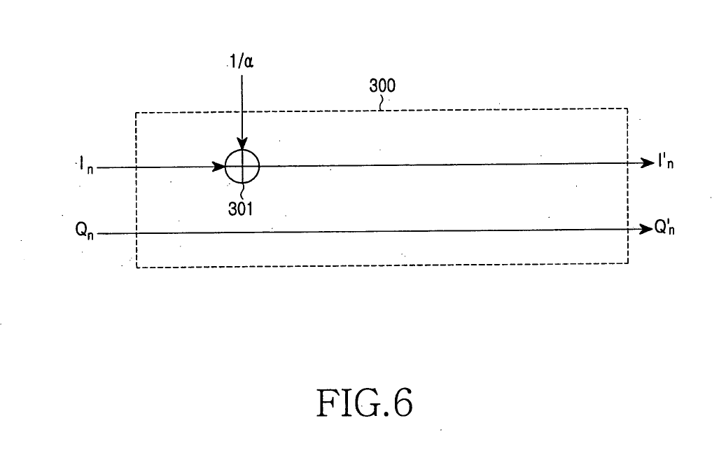

The signal from which a DC offset value is removed by the offset measurement and compensation block 310 is input to the DQDM 229. The DQDM 229 shifts the center of its input signal band to a DC band. An error component included in the output of the DQDM 229 comprises only the error component that was not removed in the DAC 203. The output of the DQDM 229 is input to a gain measurer 320 according to an embodiment of the present invention. The gain measurer 320 calculates a gain value caused by the gain mismatch between an I-channel component and a Q-channel component, occurring during the D/A conversion. A detailed description of the gain measurer 320 will be made later with reference to FIG. 5.

A description will now be made of the entire operation of FIG. 3. As described in the prior art section, the DAC 203 generates distortion due to DAC gain mismatch between the I-channel path and the Q-channel path. In order to compensate for the DAC gain mismatch, the gain measurer 320 measures a DAC gain mismatch between the I-channel component and the Q-channel component and outputs the measured DAC gain mismatch to the gain compensator 300. The gain compensator 300 applies different gain values to the I-channel component and the Q-channel component using the measured DAC gain mismatch from the gain measurer 320. That is, the gain compensator 300 pre-compensates for the DAC gain mismatch occurring in the DAC 203. In this manner it is possible to compensate for the DAC gain mismatch of the DAC 203.

Next, a description will be made of the offset measurement and compensation block 310. The offset measurement and compensation block 310 detects a DC offset occurring during the A/D conversion in the ADC 227. To this end, the offset measurement and compensation block 310 calculates an average of a predetermined number of output samples of the ADC 227. The calculated average value becomes a DC-offset component of the ADC 227. The offset measurement and compensation block 310 removes the DC offset by subtracting the calculated average value from its input signal. A detailed description of the offset measurement and compensation block 310 will now be made with reference to FIG. 4.

FIG. 4 is a detailed block diagram of an offset measurement and compensation block according to an embodiment of the present invention. With reference to FIG. 4, a detailed description will now be made of a structure and operation of the offset measurement and compensation block according to an embodiment of the present invention.

In FIG. 4, Xn represents an output signal of the ADC 227. The output signal of the ADC 227 is branched into two signals: one signal is input to a sample averager 311 and another signal is input to an adder 312. The sample averager 311 accumulates a predetermined number, N, of samples, and calculates an average of the accumulated values. This calculation is made by

$$\hat{α} = \frac{{\sum }_{n = 1}^{N} {X}_{n}}{N} \qquad ( 1 )$$

The value calculated using Equation (1), as described above, becomes a DC-offset value of the ADC 227, for the following reason. That is, because a particular signal transitions to a negative (−) and a positive (+), an accumulation of the two values converges to ‘0’. Therefore, the value accumulated by the sample averager 311 becomes a DC-offset value. The value obtained by averaging N accumulated samples by the sample averager 311 using Equation (1) is input to the adder 312. Also, the output of the ADC 227 is input to the adder 312. The adder 312 receives the output signal of the sample averager 311, by which a negative sign (−) is multiplied. In other words, the adder 312 subtracts the output of the sample averager 311 from the output of the ADC 227. In this manner, it is possible to compensate for a DC-offset value generated in the ADC 227.

FIG. 5 is a detailed block diagram of a gain measurer according to an embodiment of the present invention. With reference to FIG. 5, a detailed description will now be made of a structure and operation of the gain measurer according to an embodiment of the present invention.

As described with reference to FIG. 3, the output of the DQDM 229 becomes an input signal to the gain measurer 320. The signal output from the DQDM 229 is a complex signal of an I-channel signal component In and a Q-channel signal component Qn. The gain measurer 320 branches each of the I-channel signal component In and the Q-channel signal component Qn constituting the complex signal into two signals: one signal is input to a device (not shown in FIGS. 3 and 5) for determining a predistortion value for the predistorter 201 and the other signal is input to a path error ratio calculator 321.

Referring back to FIG. 3, the output of the digital predistorter 201 is input to the gain measurer 320. The output of the digital predistorter 201, being input to the gain measurer 320, becomes another input of the path error ratio calculator 321. The path error ratio calculator 321, receiving the output of the digital predistorter 201 and the output of the DQDM 229, calculates an error ratio between an I-channel signal and a Q-channel signal using Equation (2) below.

$$α = \sqrt{( \frac{\frac{{\sum }_{n = 1}^{N} {I}_{n}^{2}}{{\sum }_{n = 1}^{N} {Q}_{n}^{2}}}{\frac{{\sum }_{n = 1}^{N} {I}_{n}^{′2}}{{\sum }_{n = 1}^{N} {Q}_{n}^{′2}}} )} \qquad ( 2 )$$

In Equation (2), α is an output value of the path error ratio calculator 321. The reason why the path error ratio is calculated as given in Equation (2) will be described below. Equation (2) is a mathematical expression given on the assumption that there is a gain mismatch component in a path of the I-channel signal component In from the DAC 227. Therefore, if it is assumed that there is a gain mismatch component in a path of the Q-channel signal component Qn, numerators representative of accumulated values of the I-channel signals will be exchanged with denumerators representative of accumulated values of the Q-channel signals.

An operation of the gain measurer 320 based on Equation (2) will be described in detail below. The gain measurer 320 squares the I-channel signal component In output from the DQDM 229 for a predetermined number, N, of samples and accumulates the squared values. At the same time, the gain measurer 320 squares the Q-channel signal component Qn output from the DQDM 229 for the predetermined number, N, of samples and accumulates the squared values. Thereafter, the gain measurer 320 calculates a ratio between the two accumulated values. Similarly, the gain measurer 320 squares each of the I-channel signal component I'n and the Q-channel signal component Q'n, output from the digital predistorter 201, for the predetermined number, N, of samples and accumulates the squared values. Thereafter, the gain measurer 320 calculates a ratio between the two accumulated values.

Next, the gain measurer 320 divides the ratio between the two phase signals output from the DQDM 229 by the ratio between the two phase signals output from the digital predistorter 201. That is, the gain measurer 320 calculates a ratio between the ratio between the signals from one device and the ratio between the signals from another device. The gain measurer 320 extracts a square root of the calculated value using a Least Mean Square (LMS) method. After calculating the path error ratio between the I-channel signal and the Q-channel signal, the gain measurer 320 outputs the result value to the gain compensator 300.

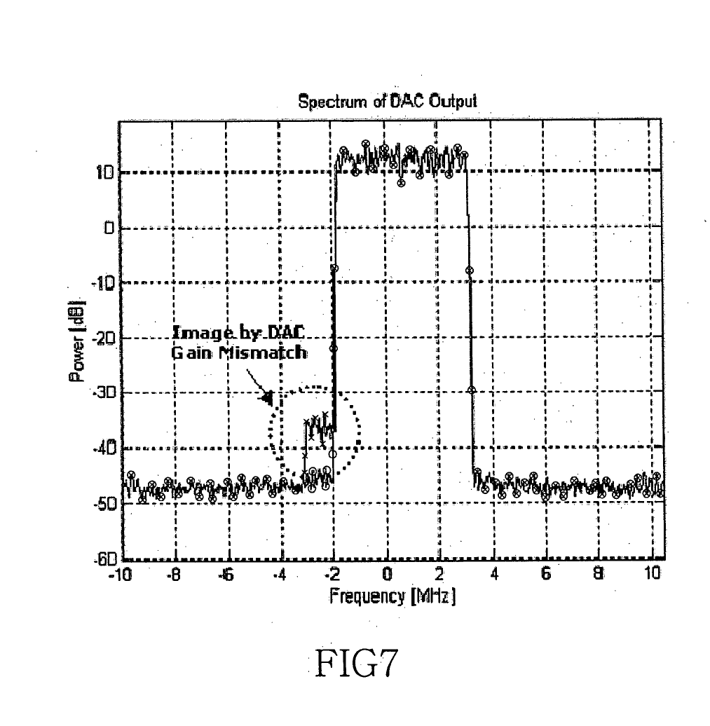

FIG. 6 is a detailed block diagram of a gain compensator according to an embodiment of the present invention. With reference to FIG. 6, a detailed description will now be made of a structure and operation of the gain compensator according to an embodiment of the present invention.

Referring to FIG. 6, it is assumed that there is an error component in a path of the I-channel signal component as described in connection with FIG. 5. Therefore, the gain compensator 300 finds a reciprocal, 1/α, of the gain value calculated in FIG. 5 and multiplies the reciprocal by the I-channel signal component In using a multiplier 301. That is, the I-channel signal component In and the Q-channel signal component Qn, which are input signals to the gain compensator 300, are both output signals of the digital predistorter 201. A gain-compensated I-channel signal component I'n obtained by multiplying the I-channel signal component In by an error component value, and the Q-channel signal component Q'n are input to the DAC 203.

Referring to both FIGS. 5 and 6, the gain measurer 320 of FIG. 5 comprises a first accumulator (not shown) for squaring each of the I-channel signal component and the Q-channel signal components output from the DQDM 229 and accumulating the squared values for a predetermined number of samples. Further, the gain measurer 320 comprises a second accumulator (not shown) for squaring each of the I-channel signal component and the Q-channel signal component output from the digital predistorter 201 and accumulating the squared values for the predetermined number of samples. In addition, the gain measurer 320 comprises a first ratio calculator (not shown) for calculating a ratio between the respective signal components from the first accumulator, and a second ratio calculator (not shown) for calculating a ratio between the respective signal components from the second accumulator.

Further, the gain measurer 320 comprises a third ratio calculator (not shown) for calculating a ratio between the ratio calculated by the first ratio calculator and the ratio calculated by the second ratio calculator. The first ratio calculator and the second ratio calculator each have a structure capable of exchanging a numerator with a denumerator before calculation. In addition, the gain measurer 320 comprises a square root calculator (not shown) for finding a square root of the output of the third ratio calculator. The gain measurer 320 can comprise a decider (not shown) for determining based on the calculated value whether there is an error in the I-channel signal component or the Q-channel signal component. The gain measurer 320 generates an application signal to be applied to the I-channel signal or the Q-channel signal according to the result determined by the decider.

The gain compensator 300 of FIG. 6 can comprise a first multiplier 301 for gain-compensating the I-channel signal component In and a second multiplier (not shown) for gain-compensating the Q-channel signal component Qn. If an application signal indicating no error is received, the two multipliers both apply a gain value ‘1’ to their input signals. However, if an application signal determined to be applied to one of two phase signals is received, the gain compensator 300 applies the gain compensation value of FIG. 5 to the phase signal component indicated by the received application signal. That is, if the gain compensation value is output as is calculated, the gain compensator 300 finds a reciprocal of the gain compensation value and multiplies the corresponding phase signal component by the reciprocal. However, if the reciprocal has already been found, it is simply multiplied by the corresponding phase signal component. Therefore, unlike the gain compensator 300 illustrated in FIG. 6, an alternative gain compensator can comprise separate multipliers in both paths.

A description will now be made of the simulation results for the case where the novel apparatus is applied and the other case where the novel apparatus is not applied.

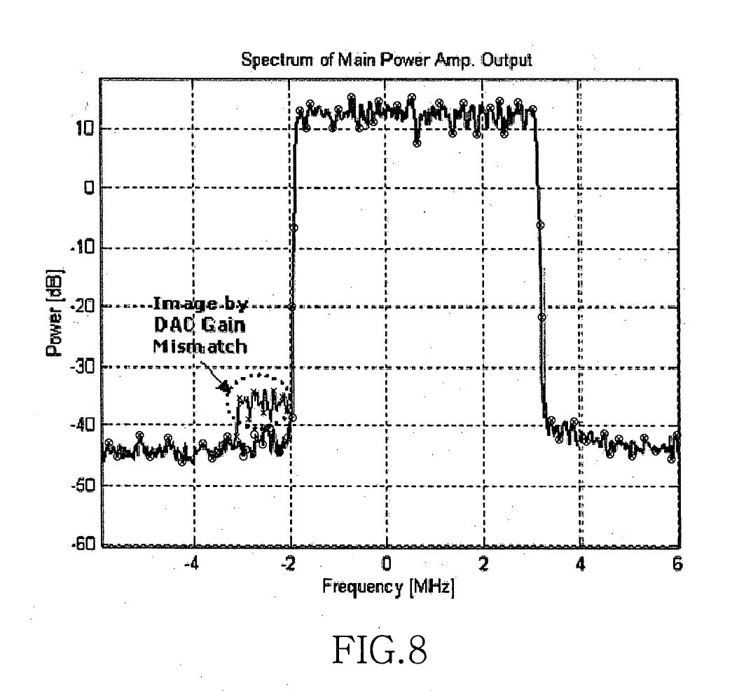

FIG. 7 is a graph illustrating simulation results for an output of a DAC in a CDMA2000 1× system according to an embodiment of the present invention and according to the prior art. The simulation of FIG. 7 was performed in the environment where the CDMA2000 1× system uses a 4-Freqeuncy Allocation (FA) configuration and 70K samples. Referring to FIG. 7, a part illustrated in a large circle represents an image generated by DAC gain mismatch, forming a curve with ‘x’s, and a curve without ‘x’s, i.e., a curve with ‘o’s represents the simulation result according to the present invention. It can be noted from the simulation results that the image generated by the DAC gain mismatch can be removed using the novel gain compensator.

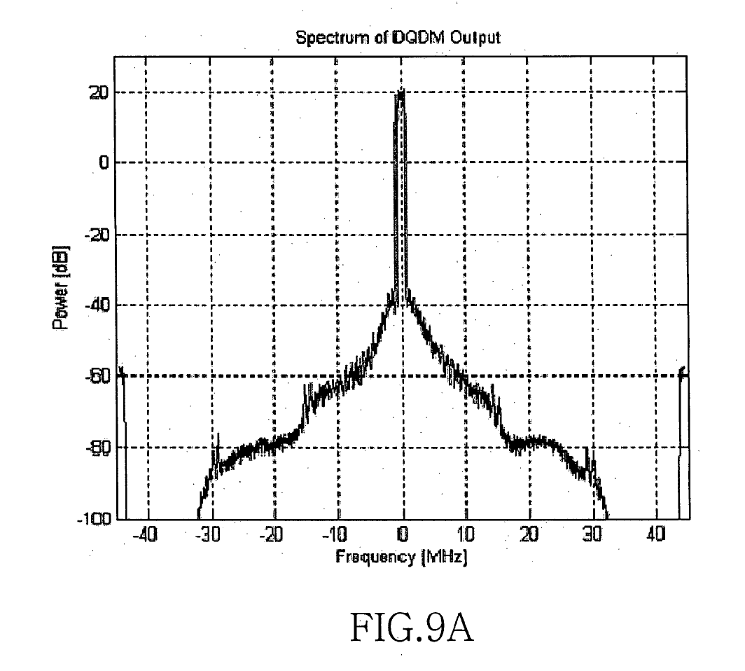

FIG. 8 is a graph illustrating simulation results for an output of a power amplifier in a CDMA2000 1× system according to an embodiment of the present invention and according to the prior art. Likewise, the simulation of FIG. 8 was performed in the environment where the CDMA2000 1× system uses a 4-FA configuration and 70K samples. Referring to FIG. 8, a part illustrated in a large circle represents an image generated by DAC gain mismatch, and a curve without the image part represents the simulation result according to the present invention. Specifically, a curve with ‘o’s represents the simulation result according to the present invention, and a curve ‘x’s represents the simulation result for the case where the present invention is not applied. It can be noted from FIG. 8 that the image generated by the DAC gain mismatch can be removed using the novel gain compensator.

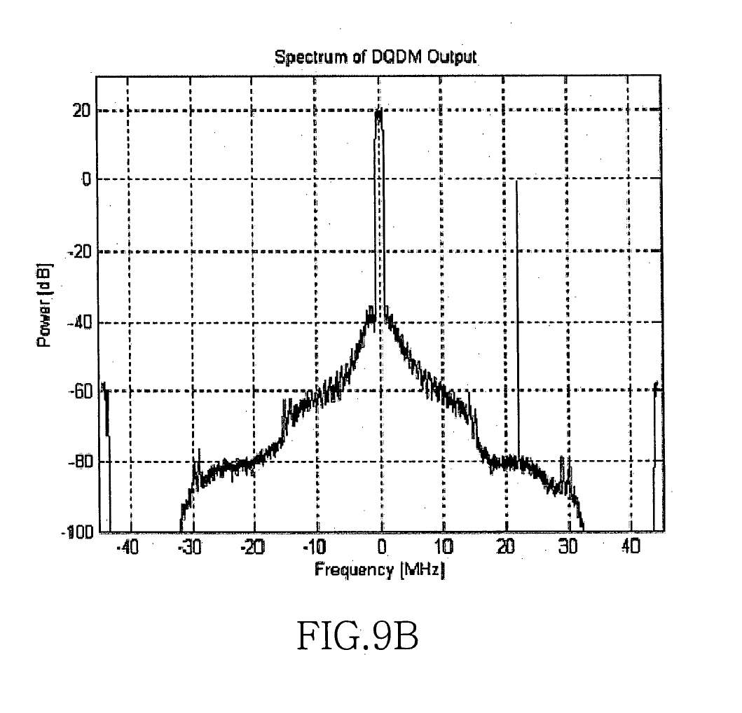

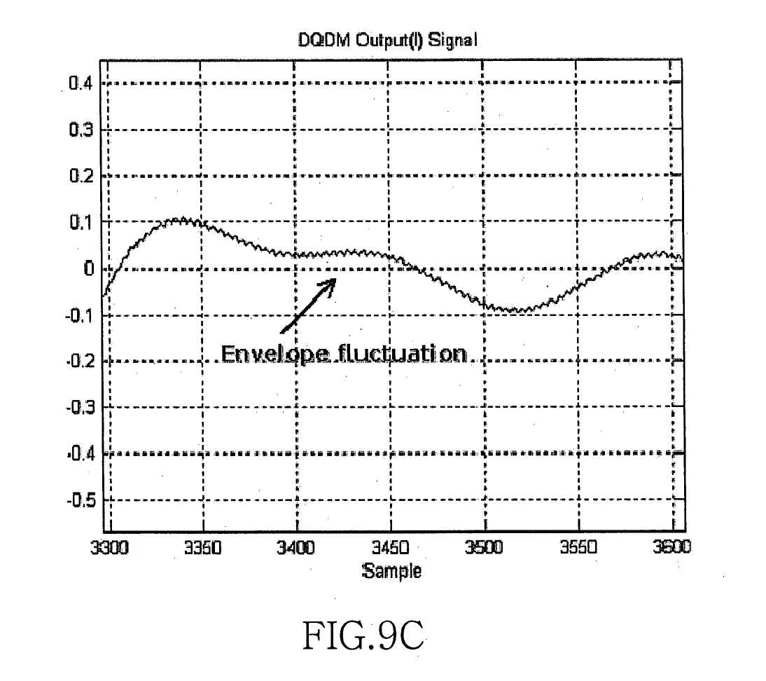

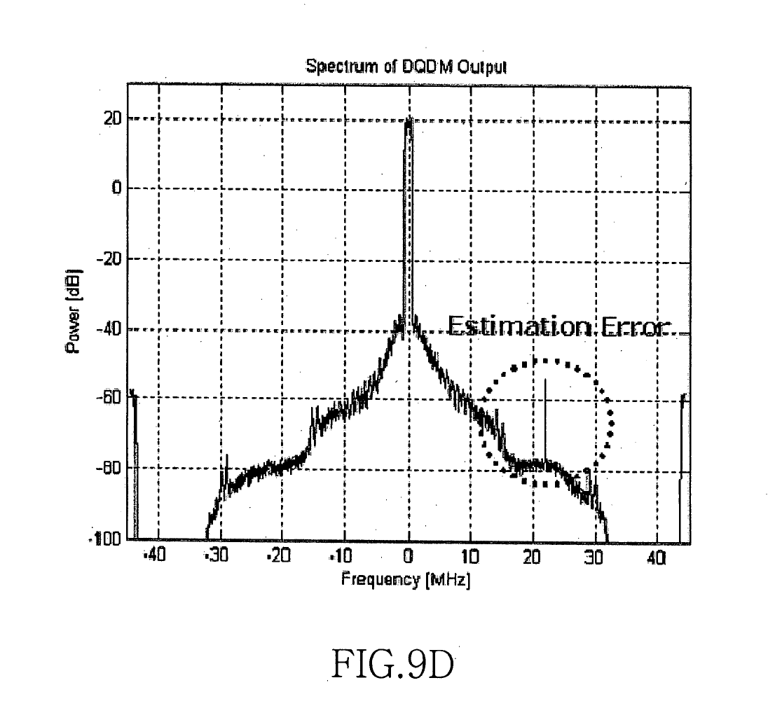

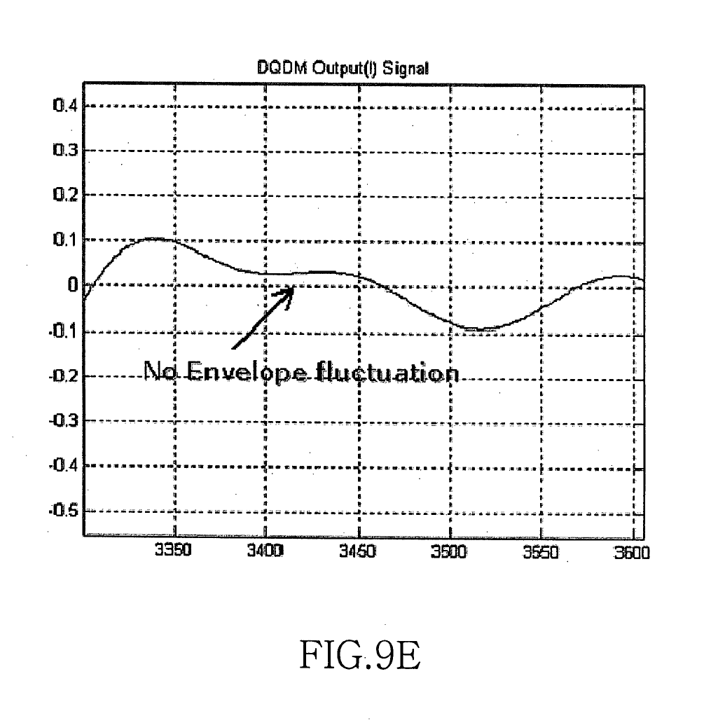

FIG. 9A is a graph illustrating simulation results for a frequency-power characteristic in the case where an output of an ADC is ideal in a CDMA2000 1× system. FIGS. 9B and 9C are graphs illustrating simulation results for the case where there is a DC offset in an output of an ADC in a CDMA2000 1× system. Specifically, FIG. 9B is a simulation graph for a frequency-power characteristic, and FIG. 9C is a graph illustrating an envelope. FIGS. 9D and 9E are graphs illustrating simulation results for the case where there is no DC offset in an output of an ADC in a CDMA2000 1× system. Specifically, FIG. 9D is a simulation graph for a frequency-power characteristic, and FIG. 9E is a graph illustrating an envelope.

The simulations of FIGS. 9A to 9E were performed in the environment where the CDMA2000 1× system has a 1-FA configuration and fixed point simulation is performed. It can be understood from FIGS. 9D and 9E that the distortion is compensated using an embodiment of the present invention.

As can be understood from the foregoing description, with the use of the novel compensators, it is possible to compensate for an error occurring due to a DAC and an ADC. In this manner, it is possible to satisfy the spurious characteristic of a transmission signal, specified in a transmission standard for a communication system, and to guarantee QoS at a receiver.

While the invention has been shown and described with reference to a certain preferred embodiment thereof, it will be understood by those skilled in the art that various changes in form and details may be made therein without departing from the spirit and scope of the invention as defined by the appended claims.

1. An apparatus for compensating for an error of a power amplifier in a digital mobile communication system having a predistorter, the apparatus comprising:
a gain compensator for pre-correcting a gain error occurring in a path of each phase signal while an in-phase signal and a quadrature-phase signal, output from the predistorter, undergo during digital-to-analog (D/A) conversion;
a digital-to-analog converter (DAC) for converting a digital signal output from the gain compensator into an analog signal; and
a transmission signal converter for converting an output of the DAC into a radio frequency (RF) signal, and outputting the RF signal to the power amplifier.

2. The apparatus of claim 1, further comprising:
a feedback converter for feeding back a part of output signals of the power amplifier, down-converting the feedback signal, converting the down-converted signal into a digital signal, and outputting an in-phase signal and a quadrature-phase signal; and
a gain measurer for calculating a gain error in a path of each signal output from the feedback converter, calculating a correction value using an output value of the predistorter, and outputting the calculated correction value to the gain compensator.

3. The apparatus of claim 2, further comprising:
an offset measurement and compensation block for measuring an offset in a path of each signal output from the feedback converter and compensating for the offset; and
a digital quadrature digital modulator (DQDM) for receiving an output of the offset measurement and compensation block, shifting a center of the received signal to a direct current (DC) band, and outputting the center-shifted signal to the gain measurer.

4. The apparatus of claim 2, wherein the gain measurer calculates the correction value using the following equation,
$$α = \sqrt{( \frac{\frac{{\sum }_{n = 1}^{N} {I}_{n}^{2}}{{\sum }_{n = 1}^{N} {Q}_{n}^{2}}}{\frac{{\sum }_{n = 1}^{N} {I}_{n}^{′2}}{{\sum }_{n = 1}^{N} {Q}_{n}^{′2}}} )}$$
where α denotes a correction value of a path, In denotes an in-phase signal component output from the DQDM, Qn denotes a quadrature-phase signal component output from the DQDM, I'n denotes an in-phase signal component output from the predistorter, Q'n denotes a quadrature-phase signal component output from the predistorter, and N denotes the number of samples.

5. The apparatus of claim 4, wherein the gain compensator performs gain compensation by multiplying a particular signal component by a reciprocal of an output value of the gain measurer.

6. The apparatus of claim 3, wherein the offset measurement and compensation block calculates an average of a predetermined number of samples for each of signal components output from the feedback converter, and determines the calculated average as a DC offset during analog-to-digital (A/D) conversion.

7. The apparatus of claim 6, wherein the offset measurement and compensation block performs offset compensation by subtracting the determined DC offset from an output signal of the feedback converter.

8. The apparatus of claim 3, wherein the offset measurement and compensation block comprises:
a sample averager for calculating an average for a predetermined number of signals from among the input signals; and
an adder for calculating a difference by subtracting an output of the sample averager from the input signals.

9. The apparatus of claim 1, wherein the gain compensator comprises:
a first multiplier for gain-compensating the in-phase signal; and
a second multiplier for gain-compensating the quadrature-phase signal.

10. The apparatus of claim 9, wherein the gain compensator applies a gain value of ‘1’ to both the first multiplier and the second multiplier when there is no error in the signal converter during signal conversion.

11. The apparatus of claim 9, wherein when there is an error in the transmission converter during signal conversion, the gain compensator gain-compensates a predistorted signal by applying a gain compensation value to a multiplier for a corresponding phase component.

12. A method of compensating for an error of a power amplifier in a digital mobile communication system having a predistorter, comprising:
pre-correcting a gain error occurring in a path of each phase signal while an in-phase signal and a quadrature-phase signal, output from the predistorter, undergo during digital-to-analog (D/A) conversion;
converting a digital signal output from the gain compensator into an analog signal; and
converting an output of a digital analog converter (DAC) into a radio frequency (RF) signal, and outputting the RF signal to the power amplifier.

13. The method of claim 12, further comprising:
feeding back a part of output signals of the power amplifier, down-converting the feedback signal, converting the down-converted signal into a digital signal, and outputting an in-phase signal and a quadrature-phase signal; and
calculating a gain error in a path of each signal output from a feedback converter, calculating a correction value using an output value of the predistorter, and outputting the calculated correction value to a gain compensator.

14. The method of claim 13, further comprising:
measuring an offset in a path of each signal output from the feedback converter and compensating for the offset via; and
receiving an output, shifting a center of the received signal to a direct current (DC) band, and outputting the center-shifted signal to the gain measurer.

15. The method of claim 13, wherein the gain measurer calculates the correction value measures a gain using the following equation,
$$α = \sqrt{( \frac{\frac{{\sum }_{n = 1}^{N} {I}_{n}^{2}}{{\sum }_{n = 1}^{N} {Q}_{n}^{2}}}{\frac{{\sum }_{n = 1}^{N} {I}_{n}^{′2}}{{\sum }_{n = 1}^{N} {Q}_{n}^{′2}}} )}$$
where α a denotes a correction value of a path, In denotes an in-phase signal component output from a digital quadrature digital modulator (DQDM), Qn denotes a quadrature-phase signal component output from the DQDM, I'n denotes an in-phase signal component output from the predistorter, Q'n denotes a quadrature-phase signal component output from the predistorter, and N denotes the number of samples.

16. The method of claim 15, wherein the gain compensator performs gain compensation by multiplying a particular signal component by a reciprocal of an output value of the gain measurer.

17. The method of claim 14, wherein the step of measuring further compnses:
calculating an average of a predetermined number of samples for each of signal components output from the feedback converter, and
determining the calculated average as a DC offset during the analog-to-digital (A/D) conversion.

18. The method of claim 17, wherein the step of calculating further comprises:
performing offset compensation by subtracting the determined DC offset from an output signal of the feedback converter.

19. The method of claim 14, wherein the step of measuring further comprises:
calculating an average for a predetermined number of signals from among the input signals; and
calculating a difference by subtracting an output of the sample averager from the input signals.

20. The method of claim 13, wherein the step of pre-correcting further comprises:
gain-compensating the in-phase signal; and
gain-compensating the quadrature-phase signal.
